(19) United States
(12) Patent Application Publication
(10) Pub. No.: US 2026/0322318 A9
(43) Pub. Date: Oct. 15, 2026

(54) ELECTRICAL POWER SUPPLY DEVICE, MOTORIZED DRIVE DEVICE COMPRISING SUCH AN ELECTRICAL POWER SUPPLY DEVICE, AND ASSOCIATED CONCEALMENT DEVICE

(71) Applicant: SOMFY ACTIVITES SA, CLUSES (FR)

(72) Inventors: Guillaume COSTANTINI, CLUSES (FR); Matthieu BONNAUD, CLUSES (FR)

(21) Appl. No.: 19/311,752

(22) Filed: Aug. 27, 2025

(30) Foreign Application Priority Data
Aug. 29, 2024 (FR) 2409225

(51) Int. Cl. H02S 20/30; E06B 9/24; E06B 9/42; E06B 9/72

(52) U.S. Cl. CPC H02S 20/30; E06B 9/42; E06B 9/72; E06B 2009/2476

(57) ABSTRACT

An electrical power supply device comprises a casing, a photovoltaic panel, which is fixed on the casing, and a fixing device, which comprises a fixing support, a holding device and a cover. The support comprises a plurality of first locking elements. The holding device comprises at least one second locking element, which cooperates with one of the first locking elements. The holding device is fixed on the cover. The cover is fixed removably on the casing. Furthermore, the support is arranged between the casing and the cover, so as, on the one hand, to be able to slide the support between the casing and the cover and, on the other hand, to hold the support in position by the holding device.

### CROSS-REFERENCE TO RELATED APPLICATION

This application claims priority to FR patent application No 2409225 filed Aug. 29, 2024, the entire content of which is hereby incorporated by reference.

### BACKGROUND OF THE INVENTION

### Field of the Invention

The present invention relates to an electrical power supply device.

The present invention also relates to a motorized driving device comprising such an electrical power supply device, as well as a shading device comprising such a motorized driving device.

In general, the present invention relates to the field of shading devices comprising a motorized driving device that moves a screen, between at least one first position and at least one second position.

A motorized driving device comprises an electromechanical actuator for a movable element of closure, shading or solar protection, such as a shutter, a door, a gate, a blind or any other equivalent material, hereafter called a screen.

### Description of the Related Art

Document WO 2010/119876 A1 is already known, which describes an electrical power supply device. The electrical power supply device comprises a casing, a photovoltaic panel and a fixing device. The photovoltaic panel is fixed on the casing. The fixing device comprises a fixing support and a holding device. The fixing support comprises a plurality of first locking elements. The holding device comprises two second locking elements. Each of the second locking elements cooperates with one of the first locking elements.

This electrical power supply device presents the disadvantage that the fixing device is integrated to the casing, on which the photovoltaic panel is fixed, given that the holding device is housed inside the casing.

Thus, the fixing support is configured, on the one hand, to slide according to a movement in translation inside the casing and, on the other hand, to be held by the holding device, during the cooperation of the two second locking elements with one of the first locking elements, which are arranged inside the casing.

This construction of the electrical power supply device implies necessarily assembling the sub-assembly formed by the casing and the photovoltaic panel on a wall with the fixing device and, more particularly, with the fixing support.

Therefore, the casing cannot be fixed on the same wall or another wall, such as, for example, a wall of a box of a shading device, a wall of a building, one of the lateral slides of a shading device, a pane of a window or a frame of a window, by means of another fixing device, which can be implemented, for example, by gluing, either by means of an adhesive, or by means of a glue layer, by elastic snap-fit, by interlocking, by screwing or by riveting to the wall.

### SUMMARY OF THE INVENTION

The present invention aims to solve the aforementioned disadvantages and to propose an electrical power supply device, a motorized driving device comprising such an electrical power supply device, as well as a shading device comprising such a motorized driving device, allowing to completely dissociate a fixing device from the electrical power supply device relative to a casing, on which a photovoltaic panel is fixed.

In this regard, the present invention aims, according to a first aspect, an electrical power supply device,
the electrical power supply device comprising at least:
   a casing,
   a photovoltaic panel, the photovoltaic panel being fixed on the casing, and
   a fixing device,
the fixing device comprising at least:
   a fixing support, the fixing support comprising at least a plurality of first locking elements, and
   a holding device, the holding device comprising at least one second locking element, said at least one second locking element cooperating with one of the first locking elements.

According to the invention, the fixing device further comprises a cover. The holding device is fixed on the cover. The cover is removably fixed on the casing. Furthermore, the fixing support is arranged between the casing and the cover, so as, on the one hand, to be able to slide the fixing support between the casing and the cover according to a movement in translation and, on the other hand, to hold the fixing support in position by the holding device, during the cooperation of said at least one second locking element with one of the first locking elements.

Thus, this construction of the electrical power supply device allows to completely dissociate the fixing device relative to the casing, on which the photovoltaic panel is fixed.

In this way, this construction of the electrical power supply device allows to adjust the position of the photovoltaic panel relative to the fixing support by means of different adjustment notches obtained by the cooperation of said at least one second locking element of the holding device cooperating with one of the first locking elements of the fixing support.

Furthermore, the photovoltaic panel is suspended relative to the fixing support by means of the casing, the holding device and the cover.

Moreover, the photovoltaic panel can be mounted on the fixing support or removed from the fixing support by sliding, according to the movement in translation, a sub-assembly formed by the photovoltaic panel, the casing, the holding device and the cover relative to the fixing support.

According to an advantageous feature of the invention, the fixation of the cover on the casing is implemented by an elastic snap-fit.

According to another advantageous feature of the invention, the casing comprises at least a first groove and a second groove. The cover comprises at least a first edge, a second edge, a first lug and a second lug. The second edge is opposite the first edge. The or each first lug is arranged along the first edge. The or each first lug is elastically deformable. The or each second lug is arranged along the second edge. Furthermore, the fixation of the cover on the casing is implemented by inserting the or each first lug into the first groove and by inserting the or each second lug into the second groove.

According to another advantageous feature of the invention, the cover further comprises two cutouts. The holding device further comprises two protruding elements and at least one slot. Each protruding element is housed inside one of the cutouts. Furthermore, a part of the holding device is elastically deformed by means of the slot, during the insertion of each protruding element inside one of the cutouts of the cover.

According to another advantageous feature of the invention, the fixing support is breakable by means of break lines.

According to another advantageous feature of the invention, each of the break lines extends through one of the first locking elements.

The present invention aims, according to a second aspect, a motorized driving device,
the motorized driving device comprising at least:
   an electromechanical actuator,
   an electronic control unit, and
   an electrical power supply device,
the electromechanical actuator comprising at least one electric motor.

According to the invention, the electrical power supply device is according to the invention and such as mentioned above. The electrical power supply device further comprises a battery, the electronic control unit and the electric motor being supplied in electrical energy from the battery.

This motorized driving device presents features and advantages similar to those described previously relative to the electrical power supply device according to the invention.

According to another advantageous feature of the invention, the battery is supplied in electrical energy by means of the photovoltaic panel.

The present invention aims, according to a third aspect, a shading device,
the shading device comprising at least:
   a screen, and
   a motorized driving device.

According to the invention, the motorized driving device is according to the invention and such as mentioned above, the screen being configured to be driven in displacement by the electromechanical actuator of the motorized driving device.

According to another advantageous feature of the invention, the shading device further comprises at least one box. The electromechanical actuator is housed inside the box. The fixing support comprises at least a first wall, a second wall and a stop. The second wall is connected to the first wall, so as to form a corner between the second wall and the first wall. The or each stop is provided in the corner. Furthermore, the box is in abutment against the or each stop.

### BRIEF DESCRIPTION OF THE DRAWINGS

Other features and advantages of the invention will appear in the following description, made with reference to the appended drawings, given as non-limiting examples and in which:

FIG. 1 is a schematic cross-sectional view of a shading installation according to one embodiment of the invention;

FIG. 2 is a schematic perspective view of the shading installation illustrated in FIG. 1;

FIG. 3 is a schematic perspective view of a motorized driving device according to the invention of the shading installation illustrated in FIGS. 1 and 2, this motorized driving device comprising an electromechanical actuator and a winding tube;

FIG. 4 is a schematic sectional view of the motorized driving device illustrated in FIG. 3, according to a sectional plane passing through a rotation axis of an output shaft of the electromechanical actuator, this schematic sectional view being locally interrupted;

FIG. 5 is a first schematic perspective view of an electrical power supply device according to the invention of the shading installation illustrated in FIGS. 1 and 2, according to a first viewing angle;

FIG. 6 is a second schematic perspective view of the electrical power supply device illustrated in FIG. 5, according to a second viewing angle, which is different from the first viewing angle;

FIG. 7 is a schematic exploded perspective view of a fixing device of the electrical power supply device illustrated in FIGS. 5 and 6;

FIG. 8 is a schematic perspective view and on a larger scale of a fixing support of the fixing device illustrated in FIGS. 5 to 7, according to a viewing angle different from that of FIGS. 5 to 7;

FIG. 9 is a schematic sectional view of the electrical power supply device illustrated in FIGS. 5 and 6, where the fixing support is fixed against a ceiling of a building; and

FIG. 10 is a schematic sectional view of the electrical power supply device illustrated in FIGS. 5 and 6, where the fixing support is fixed against a box of a shading device.

### DETAILED DESCRIPTION

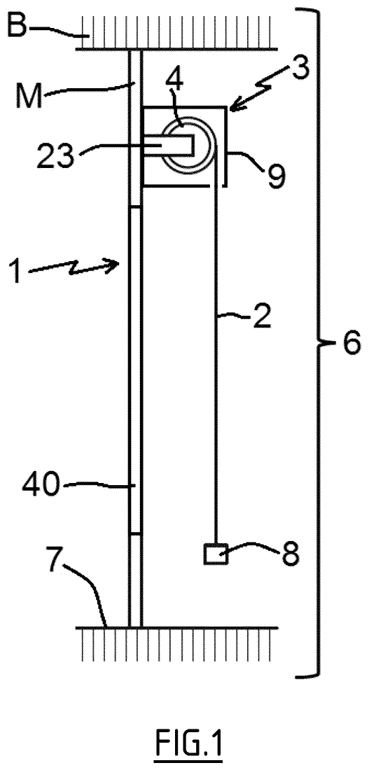

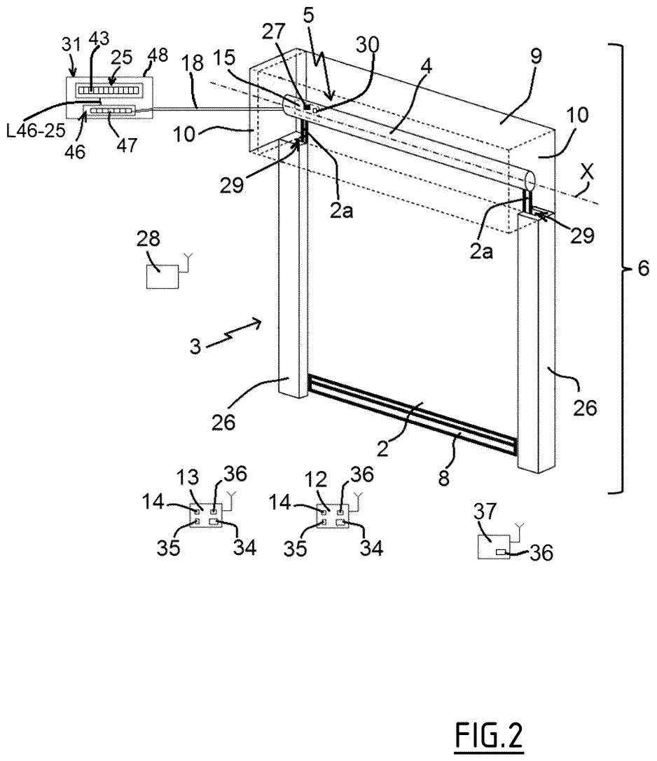

First of all, a shading installation 6 according to one embodiment of the invention is described, with reference to FIGS. 1 and 2. This shading installation 6 comprises at least one shading device 3. This shading installation 6, installed in a building B, includes at least one opening 1, in which a window 40 or a door, not represented, is arranged. This shading installation 6 is equipped with a screen 2 belonging to the shading device 3, in particular a motorized blind. The screen 2 is configured to be displaced, in other words moves, vis-a-the window 40 or the door.

A closure installation and a solar protection installation are examples of shading installations. Similarly, a closure device and a solar protection device are examples of shading devices.

The closure, shading or solar protection installation is hereafter called “shading installation”6.

The closure, shading or solar protection device is hereafter called “shading device” 3. The shading device 3 comprises the screen 2.

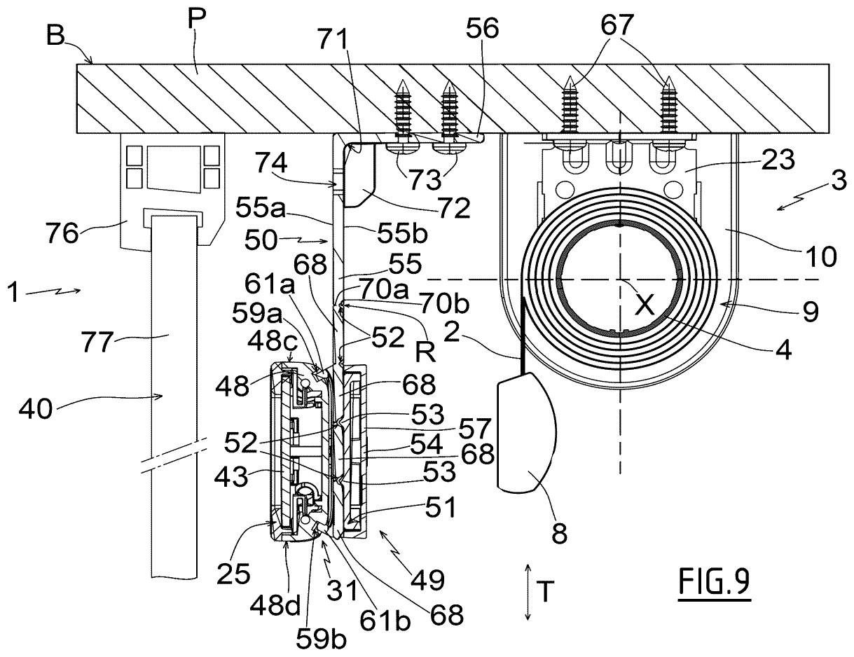

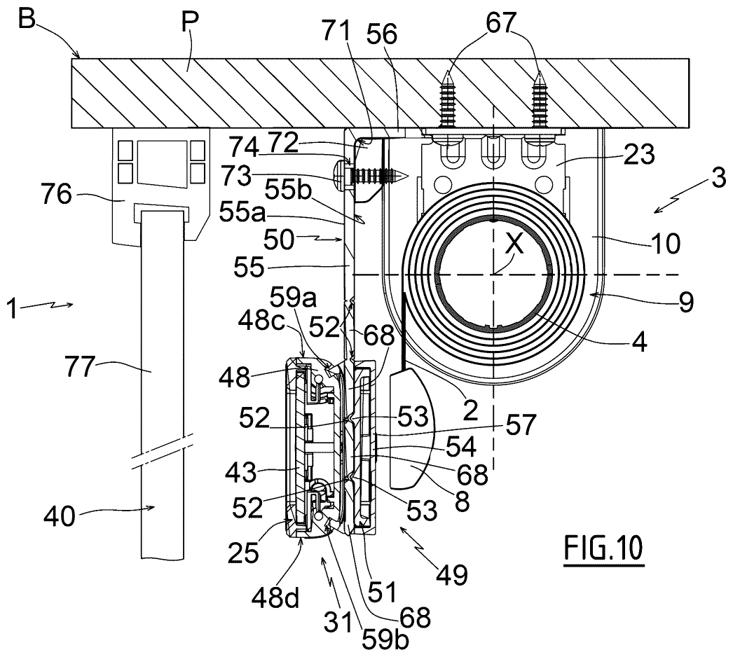

Advantageously, the window 40 comprises at least one frame 76 and at least one pane 77, as illustrated only in FIGS. 9 and 10. The pane 77 is arranged inside the frame 76, in particular in an assembled configuration of the window 40.

Here and as illustrated in FIGS. 9 and 10, the pane 77 is mounted in the frame 76. In such a case, the pane 77 is fixed relative to the frame 76.

In a variant, not represented, the window 40 further comprises at least one sash. The pane 77 is mounted in a frame of the sash. In such a case, the pane 77 is movable relative to the frame 76, in particular according to a rotational movement, especially in the case of a tilting or swinging window, or according to a movement in translation, especially in the case of a sliding window according to a horizontal or vertical direction, or according to two rotational movements, especially in the case of a tilt-and-turn window.

Here, the shading device 3 is arranged inside the building B and, more particularly, fixed on an interior face of the frame 76 of the window 40, which is not illustrated in the figures, on an interior face of a wall M of the building B, as illustrated in FIG. 1, or on a ceiling P of the building B, as illustrated in FIGS. 9 and 10. The screen 2 is configured to be deployed in front of the window 40 of the building B, in other words to cover the window 40 in a deployed configuration.

The shading device 3 can be a blind, especially a blind comprising a rollable fabric, a pleated or honeycomb fabric, or slats that can be oriented, a roller shutter or a swinging shutter.

The present invention applies to all types of shading devices 3, which can be arranged either inside the building B, or outside the building B, or with a first part of the shading devices 3 arranged inside the building B and with a second part of the shading devices 3 arranged outside the building B.

Here, the shading installation 6 comprises the shading device 3.

A motorized roller blind forming a shading device 3 is described, with reference to FIGS. 1 and 2.

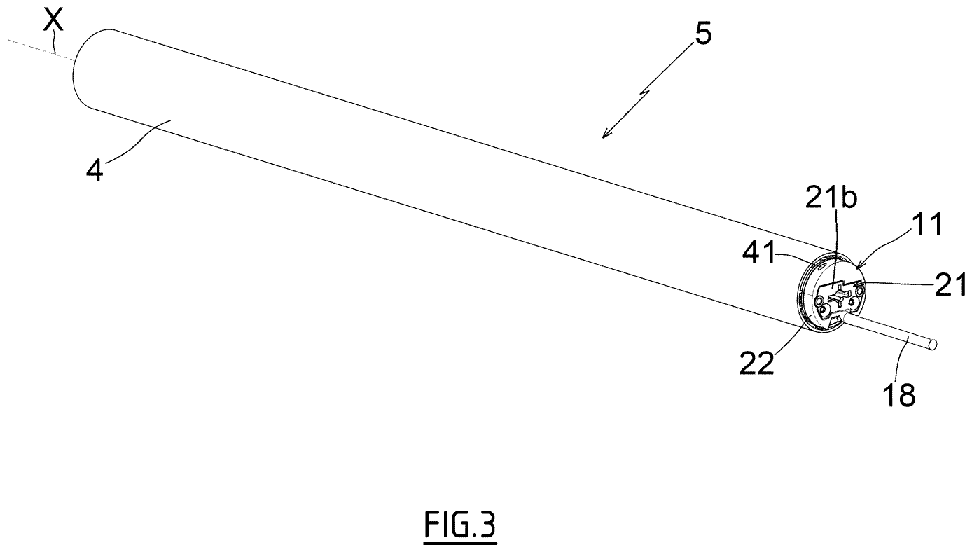

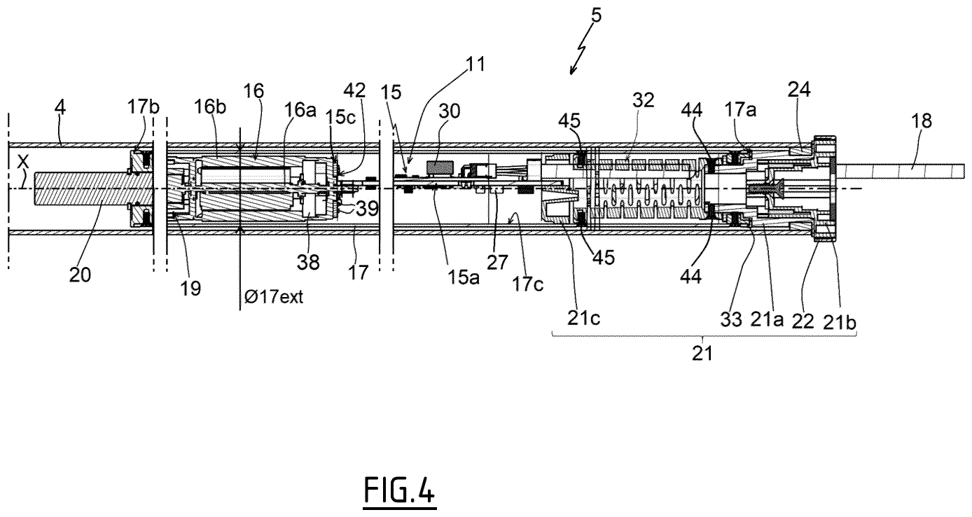

Advantageously, the shading device 3 comprises a motorized driving device 5. The motorized driving device 5 comprises an electromechanical actuator 11 illustrated in FIGS. 3 and 4.

The screen 2 is configured to be displaced, in other words is displaced, by means of the motorized driving device 5 and, more particularly, by the electromechanical actuator 11.

Here, the motorized driving device 5 and, therefore, the shading device 3 further comprises a winding tube 4. Furthermore, the winding tube 4 is arranged so as to be driven in rotation, in other words is driven in rotation, by the electromechanical actuator 11.

Here, the screen 2 is rollable on the winding tube 4.

Thus, the screen 2 of the shading device 3 is rolled on the winding tube 4 or unrolled around it, the winding tube 4 being driven by the motorized driving device 5, in particular by the electromechanical actuator 11.

In this way, the screen 2 is movable between a rolled-up position, in particular high, and an unrolled position, in particular low, and vice versa.

The screen 2 of the shading device 3 is a closure, shading and/or solar protection screen, rolling and unrolling around the winding tube 4.

Advantageously, the shading device 3 comprises a holding device 9, 23.

Advantageously, the holding device 9, 23 can comprise two supports 23. A support 23 is arranged at each end of the winding tube 4, in particular in an assembled configuration of the shading device 3.

Thus, the winding tube 4 is held by means of the supports 23. Only one of the supports 23 is visible in FIGS. 1, 9 and 10, and they are not represented in FIG. 2. The supports 23 allow to mechanically link the shading device 3 to the structure of the building B, especially to the wall M or the ceiling P of the building B.

In the two embodiments illustrated in FIGS. 9 and 10, each support 23 is fixed to the ceiling P of the building B by screwing, in particular by means of fixing screws 67, in this case two in number.

The type and the number of elements for fixing each support to the structure of the building are not limiting and can be different. The type of fixing elements can be, for example, by gluing or magnetization. The number of fixing elements can be, for example, greater than or equal to three.

Advantageously, the holding device 9, 23 can comprise a box 9. Furthermore, the winding tube 4 and at least a part of the screen 2 are housed inside the box 9, in particular in the assembled configuration of the shading device 3.

In general, the box 9 is arranged above the opening 1, or even in the upper part of the opening 1.

Here and as illustrated in FIGS. 1, 9 and 10, the supports 23 are also housed inside the box 9.

Advantageously, the box 9 comprises two cheeks 10, such as illustrated in FIGS. 2, 9 and 10, of which only one is visible in FIGS. 9 and 10. A cheek 10 is arranged at each end of the box 9, in particular in the assembled configuration of the shading device 3.

In a variant, represented in FIG. 2, the winding tube 4 is held by means of the box 9, in particular by means of the cheeks 10 of the box 9, without using supports, such as the supports 23 mentioned above.

Advantageously, the electromechanical actuator 11 is housed, in other words is mounted, inside the box 9, in particular in the assembled configuration of the shading device 3.

Advantageously, the shading device 3 can also comprise two lateral slides 26, as illustrated only in FIG. 2. Each lateral slide 26 comprises a groove 29. Each groove 29 of one of the lateral slides 26 cooperates, in other words is configured to cooperate, with a lateral edge 2a of the screen 2, in particular in the assembled configuration of the shading device 3, so as to guide the screen 2, during the rolling and unrolling of the screen 2 around the winding tube 4.

The electromechanical actuator 11 is, for example, of the tubular type. It allows to rotate the winding tube 4 around a rotation axis X, so as to displace, in particular unroll or roll, the screen 2 of the shading device 3.

In a mounted state of the shading device 3, the electromechanical actuator 11 is inserted into the winding tube 4.

Advantageously, the shading device 3 further comprises a load bar 8. The load bar 8 is configured to exert tension on the screen 2.

The roller blind, which forms the shading device 3, includes a fabric, forming the screen 2 of the roller blind 3. A first end of the screen 2, in particular the upper end of the screen 2, in the assembled configuration of the shading device 3, is fixed to the winding tube 4. Furthermore, a second end of the screen 2, in particular the lower end of the screen 2, in the assembled configuration of the shading device 3, is fixed to the load bar 8.

Here, the fabric forming the screen 2 is realized from a textile material.

In one embodiment, not represented, the first end of the screen 2 presents a hem through which a rod is arranged, in particular of plastic material. This hem realized at the first end of the screen 2 is obtained by means of sewing the fabric forming the screen 2. During the assembly of the screen 2 on the winding tube 4, the hem and the rod located at the first end of the screen 2 are inserted by sliding into a groove, not represented, arranged on the outer face of the winding tube 4, in particular along the entire length of the winding tube 4, so as to secure the screen 2 with the winding tube 4 and to be able to roll and unroll the screen 2 around the winding tube 4.

The mode of fixing the screen 2 on the winding tube 4 is not limiting and can be different. It can be implemented, for example, by means of an adhesive or one or more joints, fixed, especially by screwing or riveting, to the winding tube 4.

Whatever the embodiment, the first end of the screen 2 is arranged at the holding device 9, 23.

In the case of a roller blind, the high rolled-up position corresponds to a predetermined high end-of-travel position, or even to the bearing of the load bar 8 of the screen 2 against an edge of the box 9 of the roller blind 3, and the low unrolled position corresponds to a predetermined low end-of-travel position, or to the bearing of the load bar 8 of the screen 2 against a threshold 7 of the opening 1, or even to the complete unrolling of the screen 2.

Advantageously, the motorized driving device 5 is controlled by a command unit. The command unit can be, for example, a local command unit 12 or a central command unit 13.

Advantageously, the local command unit 12 can be connected, in a wired or wireless connection, with the central command unit 13.

Advantageously, the central command unit 13 can control the local command unit 12, as well as other similar local command units distributed in the building B.

The motorized driving device 5 is, preferably, configured to execute displacement commands, especially unrolling or rolling, of the screen 2 of the shading device 3, which can be emitted, especially, by the local command unit 12 or the central command unit 13.

The shading installation 6 comprises either the local command unit 12, or the central command unit 13, or the local command unit 12 and the central command unit 13.

The motorized driving device 5, comprising the electromechanical actuator 11, belonging to the shading installation 6 and, more particularly, to the shading device 3 illustrated in FIGS. 1 and 2, is now described, in more detail with reference to FIGS. 2 to 4.

Advantageously, the electromechanical actuator 11 comprises an electric motor 16.

Advantageously, the electric motor 16 comprises a rotor 16a and a stator 16b, positioned coaxially around the rotation axis X, which is also the rotation axis of the winding tube 4 in the mounted configuration of the motorized driving device 5, as mentioned above.

Advantageously, the electric motor 16 can be of the brushless type with electronic commutation, also called “BLDC” (acronym for the Anglo-Saxon term BrushLess Direct Current) or “synchronous with permanent magnets,”or of the direct current type.

Control means of the electromechanical actuator 11, allowing the displacement of the screen 2 of the shading device 3, is constituted of at least one electronic control unit 15. This electronic control unit 15 belongs to the motorized driving device 5 and, advantageously, to the electromechanical actuator 11 and is able to operate the electric motor 16 of the electromechanical actuator 11 and, in particular to allow the electrical power supply of the electric motor 16.

Thus, the electronic control unit 15 controls, especially, the electric motor 16, so as to open or close the screen 2, as described previously.

The control means of the electromechanical actuator 11 comprises hardware and/or software means.

As a non-limiting example, the hardware means can comprise at least one microcontroller 30.

Advantageously, the electronic control unit 15 further comprises a first communication module 27, in particular for receiving command orders, the command orders being emitted by an order transmitter, such as the local command unit 12 or the central command unit 13, these orders being intended to control the motorized driving device 5.

Advantageously, the first communication module 27 of the electronic control unit 15 is of the wireless type. In particular, the first communication module 27 is configured to receive radio command orders.

Advantageously, the first communication module 27 can also allow the reception of command orders transmitted by wired means.

Advantageously, the electronic control unit 15, the local command unit 12 and/or the central command unit 13 can be in communication with a weather station, not represented, arranged inside the building B or remotely outside the building B, including, especially, one or more sensors able to be configured to determine, for example, a temperature, a brightness, or even a wind speed, in the case where the weather station is remotely outside the building B.

Advantageously, the electronic control unit 15, the local command unit 12 and/or the central command unit 13 can also be in communication with a server 28, such as illustrated in FIG. 2, so as to control the electromechanical actuator 11 according to data made available remotely by means of a communication network, in particular an internet network that can be connected to the server 28.

The electronic control unit 15 can be controlled from the local command unit 12 and/or the central command unit 13. The local command unit 12 and/or the central command unit 13 is provided with a control keyboard. The control keyboard of the local command unit 12 or the central command unit 13 comprises one or more selection elements 14 and, eventually, one or more display elements 34.

As non-limiting examples, the selection elements can be push buttons and/or touch keys. The display elements can be light-emitting diodes and/or a display, for example LCD (acronym for the Anglo-Saxon term “Liquid Crystal Display”) or TFT (acronym for the Anglo-Saxon term “Thin Film Transistor”). The selection and display elements can also be performed by means of a touch screen.

Advantageously, the local command unit 12 and/or the central command unit 13 comprises at least one second communication module 36.

Thus, the second communication module 36 of the local command unit 12 or the central command unit 13 is configured to emit, in other words emits, command orders, in particular by wireless means, for example radio, and/or by wired means.

Furthermore, the second communication module 36 of the local command unit 12 or the central command unit 13 can also be configured to receive, in other words receives, command orders, in particular through the same means.

Advantageously, the second communication module 36 of the local command unit 12 or the central command unit 13 is configured to communicate, in other words communicates, with the first communication module 27 of the electronic control unit 15.

Thus, the second communication module 36 of the local command unit 12 or the central command unit 13 exchanges command orders with the first communication module 27 of the electronic control unit 15, either unidirectionally, or bidirectionally.

Advantageously, the local command unit 12 is a control point, which can be fixed or mobile. A fixed control point can be a control box intended to be fixed on a facade of the wall M of the building B or on a face of the frame 76 of the window 40 or the door. A mobile control point can be a remote control, a smartphone or a tablet.

Advantageously, the local command unit 12 and/or the central command unit 13 further comprises a controller 35.

The motorized driving device 5, in particular the electronic control unit 15, is, preferably, configured to execute displacement command orders, especially closing and opening, of the screen 2 of the shading device 3. These command orders can be emitted, especially, by the local command unit 12 or by the central command unit 13.

The motorized driving device 5 can be controlled by the user, for example by receiving a command order corresponding to pressing one or more of the selection elements 14 of the local command unit 12 or the central command unit 13.

Advantageously, the shading installation 6 further comprises at least one sensor 37.

In addition or in a variant, the sensor 37 can be integrated into the weather station.

Advantageously, the sensor 37 comprises at least one second communication module 36, such as the one described with reference to the local command unit 12 or the central command unit 13. Furthermore, the second communication module 36 of the sensor 37 is configured to communicate, in other words communicates, with the first communication module 27 of the electronic control unit 15.

Advantageously, the sensor 37 can be, for example, a light sensor, a temperature sensor, a humidity sensor or a wind sensor.

Thus, the motorized driving device 5 can also be automatically controlled by receiving a command order corresponding to at least one signal from the sensor 37.

In addition or in a variant, the motorized driving device 5 can also be automatically controlled by receiving a command order corresponding to at least one signal coming from a clock, not represented, of the electronic control unit 15, in particular from the microcontroller 30.

In addition or in a variant, the sensor 37 and/or the clock can be integrated into the local command unit 12 or the central command unit 13.

Advantageously, the electromechanical actuator 11 further comprises a casing 17, in particular tubular. Furthermore, the electric motor 16 is mounted inside the casing 17, in particular in an assembled configuration of the electromechanical actuator 11.

Here, the casing 17 is hollow. The casing 17 comprises a first end 17a and a second end 17b. The second end 17b is opposite the first end 17a.

Advantageously, the electromechanical actuator 11 further comprises a crown 24, in other words a sleeve.

The crown 24 is arranged, in other words is configured to be arranged, near the first end 17a of the casing 17, in particular in the assembled configuration of the electromechanical actuator 11.

The crown 24 forms, in other words is configured to form or constitute, a rotational guide bearing for the winding tube 4, around the casing 17 of the electromechanical actuator 11, in particular in an assembled configuration of the motorized driving device 5 and, therefore, of the shading device 3.

Here, the casing 17 of the electromechanical actuator 11 is cylindrical in shape, especially of revolution around the rotation axis X, and is open at each of its ends 17a, 17b.

Advantageously, the casing 17 is a tube presenting a circular section.

Here, the casing 17 is realized of a metallic material.

In a variant, the casing 17 is realized of a plastic material.

Advantageously, the electromechanical actuator 11 further comprises an output shaft 20.

Here, the output shaft 20 is arranged, in other words is configured to be arranged, near the second end 17b of the casing 17, in particular in the assembled configuration of the electromechanical actuator 11.

Advantageously, the electromechanical actuator 11 further comprises a gearbox 19.

Advantageously, the gearbox 19 comprises at least one reduction stage. The reduction stage can be an epicyclic gear train.

The type and the number of reduction stages of the gearbox are not limiting. The number of reduction stages can be, especially, equal to one or greater than or equal to two.

The gearbox 19 is partially represented in FIG. 4, due to the local interruption of this figure.

The gearbox 19 is coupled, in other words is configured to be coupled, with the electric motor 16, in particular with the rotor 16a of the electric motor 16 in the assembled configuration of the electromechanical actuator 11.

Advantageously, the electromechanical actuator 11 further comprises a brake, not represented.

As non-limiting examples, the brake can be a spring brake, a cam brake, a magnetic brake or an electromagnetic brake.

The brake is configured to brake and/or to block in rotation the output shaft 20, so as to regulate the rotation speed of the winding tube 4, during a displacement of the screen 2, and to keep the winding tube 4 blocked, when the electromechanical actuator 11 is electrically deactivated.

Here, the brake is configured to be arranged, in other words is arranged, in particular in the assembled configuration of the electromechanical actuator 11, between two reduction stages of the gearbox 19.

In a variant, not represented, the brake is configured to be arranged, in other words is arranged, in particular in the assembled configuration of the electromechanical actuator 11, between the electronic control unit 15 and the electric motor 16, in other words at the input of the electric motor 16, or between the gearbox 19 and the output shaft 20, in other words at the output of the gearbox 19, or even between the electric motor 16 and the gearbox 19, in other words at the output of the electric motor 16.

Advantageously, the gearbox 19 and, eventually, the brake are mounted, in other words are configured to be mounted, inside the casing 17 of the electromechanical actuator 11, in particular in the assembled configuration of the electromechanical actuator 11.

Advantageously, the electromechanical actuator 11 and, more particularly, the electronic control unit 15 further comprises a device, not represented, for detecting end-of-travel and/or obstacle during the displacement of the screen 2. This end-of-travel and/or obstacle detection device can be mechanical or electronic.

Advantageously, the end-of-travel and/or obstacle detection device is implemented by means of the microcontroller 30 of the electronic control unit 15 and, in particular, by means of an algorithm implemented by this microcontroller 30.

The winding tube 4 is driven in rotation around the rotation axis X and the casing 17 of the electromechanical actuator 11 while being supported by means of two pivot connections. The first pivot connection is realized at a first end of the winding tube 4 by means of the crown 24. The crown 24 thus allows to realize a bearing. The second pivot connection, not represented, is realized at a second end of the winding tube 4, opposite the first end.

Advantageously, the electromechanical actuator 11 further comprises a torque support 21.

Here, the torque support 21 is arranged at the first end 17a of the casing 17 of the electromechanical actuator 11, in particular in the assembled configuration of the electromechanical actuator 11.

The torque support 21 allows to take up the forces exerted by the electromechanical actuator 11, in particular the torque exerted by the electromechanical actuator 11, relative to the structure of the building B. The torque support 21 advantageously allows to take up, in addition, forces exerted by the winding tube 4, especially the weight of the winding tube 4, the electromechanical actuator 11 and the screen 2, and ensuring the transfer of these forces to the structure of the building B.

Thus, the torque support 21 allows to fix the electromechanical actuator 11 on the holding device 9, 23, in particular to one of the supports 23 or on one of the cheeks 10 of the box 9.

Advantageously, the torque support 21 protrudes at the first end 17a of the casing 17 of the electromechanical actuator 11.

Advantageously, the torque support 21 closes, in other words is configured to close, the first end 17a of the casing 17, in particular in the assembled configuration of the electromechanical actuator 11.

Advantageously, the torque support 21 is fixed, in other words is configured to be fixed, to the casing 17 by means of one or more fixing elements, not represented, in particular in the assembled configuration of the electromechanical actuator 11. The fixing element(s) can be, especially, bosses, fixing screws, elastic snap-fit fixing elements, grooves fitted into notches or a combination of these different fixing elements.

Advantageously, the torque support 21 comprises a first part 21a, which can also be called “fixed point,” and a second part 21b, which can also be called “actuator head.”

The first part 21a of the torque support 21 is assembled, in other words is configured to be assembled, with the casing 17, in particular in the assembled configuration of the electromechanical actuator 11. Furthermore, the second part 21b of the torque support 21 is configured to be assembled, in other words is assembled, with the holding device 9, 23, in particular in an assembled configuration of the electromechanical actuator 11 in the shading device 3.

The second part 21b of the torque support 21 is assembled, in other words is configured to be assembled, on the first part 21a of the torque support 21, in particular in the assembled configuration of the electromechanical actuator 11.

In another embodiment, the torque support 21 can be monobloc, in other words constituted of a single piece forming the first and second parts 21a, 21b of the torque support 21.

Advantageously, the second part 21b of the torque support 21 can present different external shapes, especially a splined shape, called “star-shaped,” in other words comprising reliefs on its contour, or a round shape, in other words devoid of reliefs on its contour, as illustrated in FIG. 3.

Advantageously, at least one portion of the first part 21a of the torque support 21 is generally cylindrical in shape and is arranged, in other words is configured to be arranged, inside the casing 17, in particular in the assembled configuration of the electromechanical actuator 11.

Advantageously, an outer diameter of at least one portion of the second part 21b of the torque support 21 is equal to or, eventually, greater than the outer diameter Ø17ext of the casing 17.

Advantageously, the torque support 21 further comprises a stop 33. Furthermore, the stop 33 is bearing, in other words is configured to bear, against the casing 17, at the first end 17a of the casing 17, in particular in the assembled configuration of the electromechanical actuator 11.

Thus, the stop 33 of the torque support 21 allows to limit the insertion of the first part 21a of the torque support 21 into the casing 17, according to the direction of the rotation axis X.

Here, the stop 33 of the torque support 21 comprises a shoulder. More particularly, it is realized in the form of a collar, in particular cylindrical in shape and with a straight generatrix.

In a variant, not represented, the stop 33 of the torque support 21 can delimit the first and second parts 21a, 21b of the torque support 21 relative to each other.

Thus, only the first part 21a of the torque support 21 is arranged inside the casing 17 of the electromechanical actuator 11, following the insertion of the torque support 21 inside the casing 17, up to the stop 33, in particular in the assembled configuration of the electromechanical actuator 11.

Here and as illustrated in FIG. 4, the crown 24 is arranged, in other words is configured to be arranged, around the torque support 21, in particular the first part 21a of the torque support 21, especially in the assembled configuration of the electromechanical actuator 11. In this case, the crown 24 is mounted free in rotation around the torque support 21, in particular the first part 21a of the torque support 21.

In a variant, not represented, the crown 24 is arranged, in other words is configured to be arranged, around a part of the casing 17, in particular in the assembled configuration of the electromechanical actuator 11. In this case, the crown 24 is mounted free in rotation around the casing 17.

In another variant, not represented, the crown 24 is arranged, in other words is configured to be arranged, on the one hand, around the torque support 21 and, on the other hand, around a part of the casing 17 of the electromechanical actuator 11, in particular the first end 17a of the casing 17, especially in the assembled configuration of the electromechanical actuator 11. In such a case, the crown 24 can be mounted free in rotation, on the one hand, around the torque support 21 and, on the other hand, around the casing 17 of the electromechanical actuator 11.

Advantageously, the electronic control unit 15 can be supplied in electrical energy by means of an electrical power cable 18.

Advantageously, the electronic control unit 15 is arranged at least partly inside the casing 17 of the electromechanical actuator 11.

Moreover, the electronic control unit 15 can be arranged at least partly outside the casing 17 of the electromechanical actuator 11 and, in particular, mounted in the torque support 21.

Advantageously, the electronic control unit 15 comprises a first electronic board 15a and a second electronic board, not represented.

Here, the first electronic board 15a of the electronic control unit 15 is arranged inside the casing 17 of the electromechanical actuator 11, in particular in the assembled configuration of the electromechanical actuator 11. Furthermore, the second electronic board is arranged inside the torque support 21 of the electromechanical actuator 11, in particular in the assembled configuration of the electromechanical actuator 11.

Here, the electronic control unit 15 is devoid of a casing for receiving the first electronic board 15a. In other words, the first electronic board 15a is not mounted in a specific casing. This first electronic board 15a is, on the one hand, held, especially plugged, into the torque support 21, in particular in a third central part 21c of the torque support 21, as illustrated in FIG. 4, and, on the other hand, held, especially plugged, into a support, not represented, mounted at the end of the electric motor 16, in particular in the assembled configuration of the electromechanical actuator 11.

Advantageously, the electromechanical actuator 11 further comprises a vibration filtering module 32.

Here, the vibration filtering module 32 is integrated into the torque support 21 and, more particularly, is arranged, along the rotation axis X, between the first and third parts 21a, 21c of the torque support 21.

Here and as illustrated in FIG. 4, the vibration filtering module 32 is, on the one hand, assembled on the torque support 21 and, more particularly, fixed on the torque support 21, especially by screwing, by means of fixing screws 44, and, on the other hand, fixed to the casing 17 of the electromechanical actuator 11, especially by screwing, by means of fixing screws 45.

In a variant, not represented, the vibration filtering module 32 is distinct from the torque support 21.

Advantageously, the torque support 21 further comprises a cover 22. The cover 22 is mounted, in other words is configured to be mounted, on the torque support 21, especially on the first and/or second parts 21a, 21b of the torque support 21, in particular in the assembled configuration of the electromechanical actuator 11.

Advantageously, the torque support 21 comprises at least one housing, not represented.

Advantageously, the or at least one of the housings is formed between the first and second parts 21a, 21b of the torque support 21 and the cover 22.

Here, the second electronic board is arranged, in other words is configured to be arranged, inside the housing, in particular in the assembled configuration of the electromechanical actuator 11.

Advantageously, the torque support 21 comprises at least one selection device 41, in particular a button, which can be, for example, of the push or magnetic type.

The or each selection device 41 is configured, especially, to perform an adjustment of the electromechanical actuator 11 through one or more configuration modes, to pair the electromechanical actuator 11 with one or more control units 12, 13, to reset one or more parameters, which can be, for example, an end-of-travel position, to reset the paired control unit(s) 12, 13 or even to control the displacement of the screen 2.

Here, the torque support 21 comprises a single selection device 41.

The number of selection devices of the torque support is not limiting and can be different. It can be, especially, greater than or equal to two.

Advantageously, the torque support 21 comprises at least one display device, not represented.

The or each display device is configured, especially, to display a visual indication, which can be, for example, representative of an operating mode of the electromechanical actuator 11, in particular a configuration mode or a control mode, or even of a state of a member of the motorized driving device 5.

Here, the or each selection device 41 and the or each display device are electrically connected, in other words are configured to be electrically connected, to the electronic control unit 15 and, more precisely, to the second electronic control board, in particular in the assembled configuration of the electromechanical actuator 11.

In a variant, the or each selection device 41 and/or the or each display device are electrically connected, in other words are configured to be electrically connected, to the first electronic control board 15a, in particular in the assembled configuration of the electromechanical actuator 11.

Here, the torque support 21 comprises a single housing, where the selection device 41 and the display device are housed.

In a variant, not represented, the torque support 21 can comprise a first housing to receive the display device and a second housing to receive the selection device 41. The torque support 21 can further comprise a first housing per display device or a first housing for a plurality of display devices, in the case where the torque support 21 presents several display devices, and, eventually, a second housing per selection device 41 or a second housing for a plurality of selection devices 41, in the case where the torque support 21 presents several selection devices 41.

Advantageously, the output shaft 20 of the electromechanical actuator 11 is arranged inside the winding tube 4 and at least partly outside the casing 17 of the electromechanical actuator 11.

Here, one end of the output shaft 20 protrudes relative to the casing 17 of the electromechanical actuator 11, in particular relative to the second end 17b of the casing 17.

Advantageously, the motorized driving device 5 further comprises a connecting element, not represented. The output shaft 20 of the electromechanical actuator 11 is configured to drive in rotation, in other words drives in rotation, the connecting element, around the rotation axis X. Furthermore, the connecting element is configured to drive in rotation, in other words drives in rotation, the winding tube 4, around the rotation axis X.

Advantageously, the connecting element is connected, in other words is configured to be connected, to the winding tube 4, in particular in the assembled configuration of the motorized driving device 5.

Here, the connecting element is realized in the form of a torque transmission wheel.

When the electromechanical actuator 11 is operated, the electric motor 16 and the gearbox 19 drive in rotation, around the rotation axis X, the output shaft 20. Furthermore, the output shaft 20 drives in rotation, around the rotation axis X, the winding tube 4 by means of the connecting element.

Thus, the winding tube 4 drives in rotation the screen 2 of the shading device 3, so as to open or close the opening 1.

Advantageously, the electromechanical actuator 11 further comprises a counting device 42. The counting device 42 is configured to cooperate, in other words cooperates, with the electronic control unit 15. Furthermore, the counting device 42 and the electronic control unit 15 are configured to determine a position, which can be called “current,” of the screen 2.

Advantageously, the electronic control unit 15 is configured to monitor at least one signal from the counting device 42 at a predetermined frequency, especially depending on the position of the screen 2.

Here, the counting device 42 is of the magnetic type.

In such a case, the counting device 42 can comprise a coding wheel 38 and one or more sensors 39, in particular Hall effect sensors.

Here, the coding wheel 38 is connected to an axial end of the rotor 16a of the electric motor 16. Furthermore, the or each sensor 39 is assembled on an electronic board of the electronic control unit 15, in particular on a third electronic board 15c, or, in a variant, on the first electronic board 15a.

Thus, the counting device 42 allows to determine the number of turns realized by the rotor 16a of the electric motor 16.

Here, the counting device 42 comprises three sensors 39, of which only two are visible in FIG. 4.

The number of sensors is not limiting and can be different. It can be, for example, one or two.

In a variant, not represented, the counting device 42 can be devoid of sensors 39. In this case, the counting device 42 is configured to, in cooperation with the electronic control unit 15, analyze the electrical power supply command signals of the electric motor 16 and determine a position, which can be called “current,” of the rotor 16a of the electric motor 16 and, therefore, of the output shaft 20 of the electromechanical actuator 11 and the winding tube 4.

In a variant, not represented, the counting device 42 allows to determine the number of turns realized by the output shaft 20 of the electromechanical actuator 11.

In another variant or in addition, the crown 24 comprises, on its inner face, a toothing, not represented, configured to cooperate, in other words cooperating, with a pinion, not represented, installed inside the torque support 21 or, alternatively, inside the casing 17 of the electromechanical actuator 11. In this variant, the coding wheel 38 is connected to the pinion, in particular by means of a shaft. Thus, the toothing of the crown 24 is configured to drive in rotation, in other words drives in rotation, the pinion, so as to count the number of turns of the winding tube 4. In this case, the toothing of the crown 24 and the pinion are part of the counting device 42.

The counting device 42 also allows to determine the direction of rotation of the winding tube 4 and/or manage the end-of-travel positions of the screen 2.

The type of counting device is not limiting and can be different, in particular optical, for example, an encoder equipped with one or more optical sensors, or temporal.

The shading device 3 and, more particularly, the motorized driving device 5 further comprises an electrical power supply device 31, visible in FIGS. 2, 5, 6, 9 and 10.

The electrical power supply device 31 is electrically connected to an electrical load, in this case to the electromechanical actuator 11, by means of the electrical power cable 18.

Thus, the electrical power supply device 31 is configured to supply, in other words supplies, in electrical energy the electromechanical actuator 11 and, more particularly, the electronic control unit 15 and the electric motor 16.

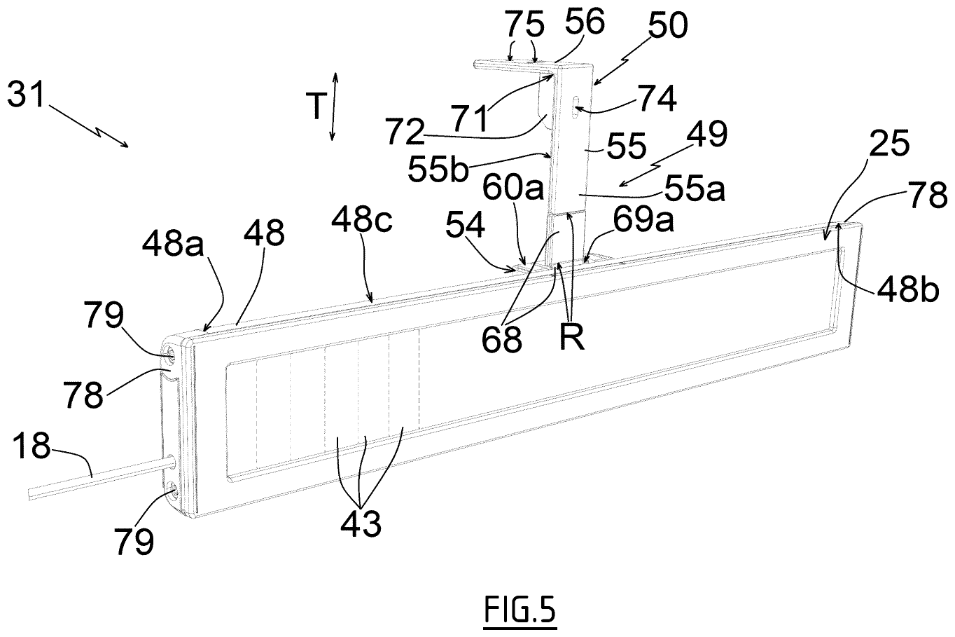

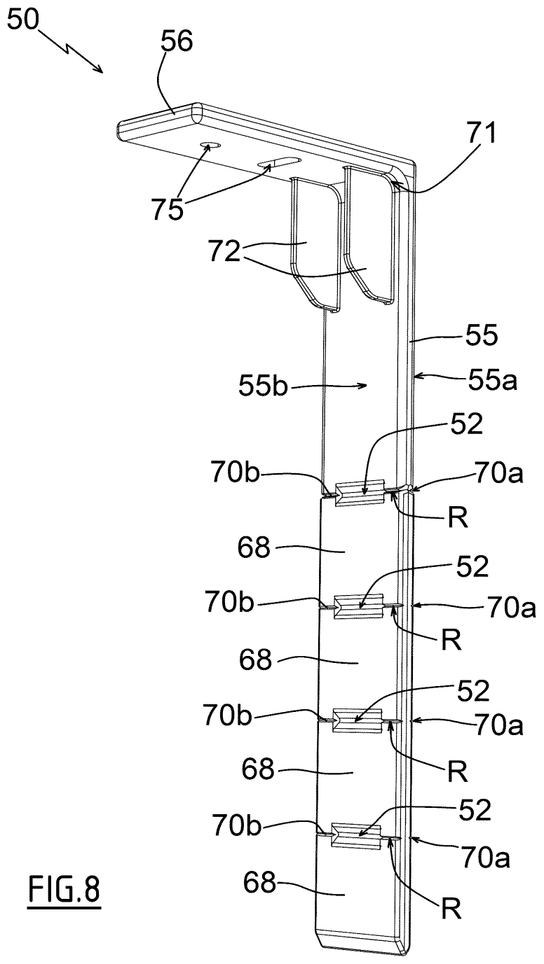

The electrical power supply device 31 comprises at least one casing 48, a photovoltaic panel 25 and a fixing device 49, such as illustrated in FIGS. 5 to 10.

Advantageously, the casing 48 comprises a first end 48a and a second end 48b. The second end 48b is opposite the first end 48a.

Advantageously, the electrical power supply device 31 further comprises two end caps 78. Each end cap 78 is fixed, in other words is configured to be fixed, at one of the first and second ends 48a, 48b of the casing 48, in particular in an assembled configuration of the electrical power supply device 31.

The fixing of each end cap 78 to one of the first and second ends 48a, 48b of the casing 48 is implemented by screwing by means of fixing screws 79.

The type of fixing of the end cap to one of the first and second ends of the casing is not limiting and can be different. It can be, for example, by elastic snap-fit, by interlocking or by riveting.

The photovoltaic panel 25 is arranged, in other words is configured to be arranged, so that solar cells 43 of it are vis-a-vis the pane 77 of the window 40 by means of the fixing device, in particular in an assembled configuration of the electrical power supply device 31 relative to the shading installation 6.

The photovoltaic panel 25 is fixed, in other words is configured to be fixed or assembled, on the casing 48, in particular in the assembled configuration of the electrical power supply device 31.

The fixing of the photovoltaic panel 25 on the casing 48 can be implemented, for example, by gluing, either by means of an adhesive, or by means of a layer of glue, by screwing, by elastic snap-fit or by interlocking.

Advantageously, the electrical power supply device 31 further comprises at least one battery 46. The battery 46 is configured to supply, in other words supplies, in electrical energy the electromechanical actuator 11, in particular the electronic control unit 15 and the electric motor 16.

In FIG. 2, the battery 46 is arranged in the casing 48. In this case, the battery 46 is outside the box 9, being given that the electrical power supply device 31 is outside the box 9.

In a variant, not represented, the battery 46 can be arranged at the box 9, in particular inside the box 9, inside the winding tube 4 while being outside the casing 17 of the electromechanical actuator 11, or inside the casing 17 of the electromechanical actuator 11, in particular in the assembled configuration of the electromechanical actuator 11. In this latter case, the electromechanical actuator 11 comprises the battery 46.

Here, the battery 46 is of the rechargeable type.

Advantageously, the photovoltaic panel 25 is configured to supply, in other words supplies, in electrical energy the battery 46.

Thus, the recharging of the battery 46 is implemented by solar energy, by means of the photovoltaic panel 25.

In this way, the electrical power supply device 31 allows to supply in electrical energy the electromechanical actuator 11 and, more particularly, the electronic control unit 15 and the electric motor 16 by means of the battery 46 and the photovoltaic panel 25, without the electromechanical actuator 11 being electrically connected to a mains power supply network.

Advantageously, the electrical power supply device 31 further comprises the electrical power cable 18.

In FIG. 2, the electrical power cable 18 electrically connects the electrical power supply device 31, in particular the battery 46, to the electronic control unit 15, which can be arranged either inside or outside the casing 17 of the electromechanical actuator 11. The photovoltaic panel 25 is electrically connected to the battery 46, by an electrical connection L46-25, being given that the battery 46 is arranged inside the casing 48 of the electrical power supply device 31. The electrical power cable 18 allows to supply in electrical energy to the electromechanical actuator 11, especially the electrical energy supply of the electronic control unit 15 and the electric motor 16.

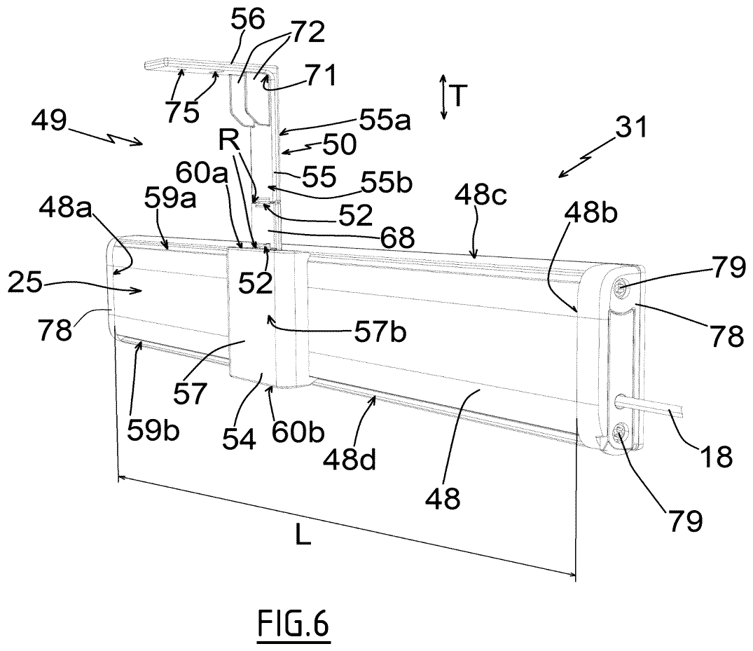

In a variant, such as illustrated in FIGS. 5 and 6, the electrical power cable 18 electrically connects the photovoltaic panel 25 to the electromechanical actuator 11, in particular to the electronic control unit 15, in the case where the battery 46 is arranged outside the casing 48 of the electrical power supply device 31 and, eventually, inside the casing 17 of the electromechanical actuator 11. In this case, an electrical connection, not represented, is implemented between the electronic control unit 15 and the battery 46.

In a variant, not represented, the electrical power cable 18 electrically connects the photovoltaic panel 25 to the battery 46, in the case where the battery 46 is arranged outside the casing 48 of the electrical power supply device 31, as well as outside the casing 17 of the electromechanical actuator 11.

In a variant, not represented, the electrical power cable 18 electrically connects the photovoltaic panel 25 to the electronic control unit 15 and the battery 46, in the case where the battery 46 is arranged outside the casing 48 of the electrical power supply device 31, as well as outside the casing 17 of the electromechanical actuator 11. In this case, the electrical power cable 18 presents several branches, especially three in number and can be, for example, in the shape of a “Y”.

Advantageously, the electrical power cable 18 comprises at least one electrical connector, not represented. Furthermore, the electrical connector or one of the electrical connectors cooperates, in other words is configured to cooperate, with another electrical connector, not represented, of the electromechanical actuator 11, of the battery 46 or the electronic control unit 15, in particular in the assembled configuration of the motorized driving device 5.

Advantageously, when the torque support 21 comprises a display device, the operating parameter of this display device allows to visualize is a charge state of the battery 46.

Advantageously, the battery 46 comprises a plurality of energy storage elements 47, in particular electrically connected in series. The energy storage elements 47 of the battery 46 can be, especially, rechargeable accumulators.

Advantageously, the photovoltaic panel 25 comprises the plurality of solar cells 43. In this case, the battery 46 is supplied in electrical energy by means of the solar cells 43 of the photovoltaic panel 25. Only some solar cells 43 are represented in FIG. 5, which is a front view of the photovoltaic panel 25.

The motorized driving device 5, in particular the photovoltaic panel 25 and/or the electronic control unit 15, comprises charging elements configured to charge the battery 46, from the solar energy recovered by the photovoltaic panel 25. In this case, the current flows between the components 25, 46 and 15 through a wired connection, at least partly by means of the electrical power cable 18.

Thus, the charging elements, configured to charge the battery 46, from solar energy, allow to convert the solar energy recovered by the photovoltaic panel 25 into electrical energy.

In a variant or in addition, the motorized driving device 5, in particular the electromechanical actuator 11, is supplied in electrical energy from the battery 46, from an auxiliary battery, not represented, or from a mains power supply network, in particular by the commercial alternating network, especially depending on a charge state of the battery 46.

In the case where the electronic control unit 15 comprises the first electronic board 15a and the second electronic board, not represented, the first electronic board 15a is configured to control, in other words controls, the electric motor 16 and the second electronic board is configured to allow to recharge the battery 46 and/or access parameterization and/or configuration functions of the electromechanical actuator 11, by means of the selection device(s) 41 and, eventually, the display device(s). The charging elements of the battery 46 can be arranged at the second electronic board.

In a variant, in the case where the electronic control unit 15 comprises a single electronic board, the single electronic board is configured to control the electric motor 16, to allow the recharge of the battery 46 and, eventually, to access parameterization and/or configuration functions of the electromechanical actuator 11, by means of the selection device(s) and, eventually, the display device(s). The charging elements of the battery 46 can be arranged at the single electronic board.

With reference to FIGS. 5 to 10, the electrical power supply device 31 is now described in greater detail, as illustrated schematically in FIG. 2 and more realistically in FIGS. 5 to 10.

The fixing device 49 comprises at least one fixing support 50 and a holding device 51.

The fixing support 50 comprises at least a plurality of first locking elements 52, as illustrated in FIGS. 6 and 8 to 10.

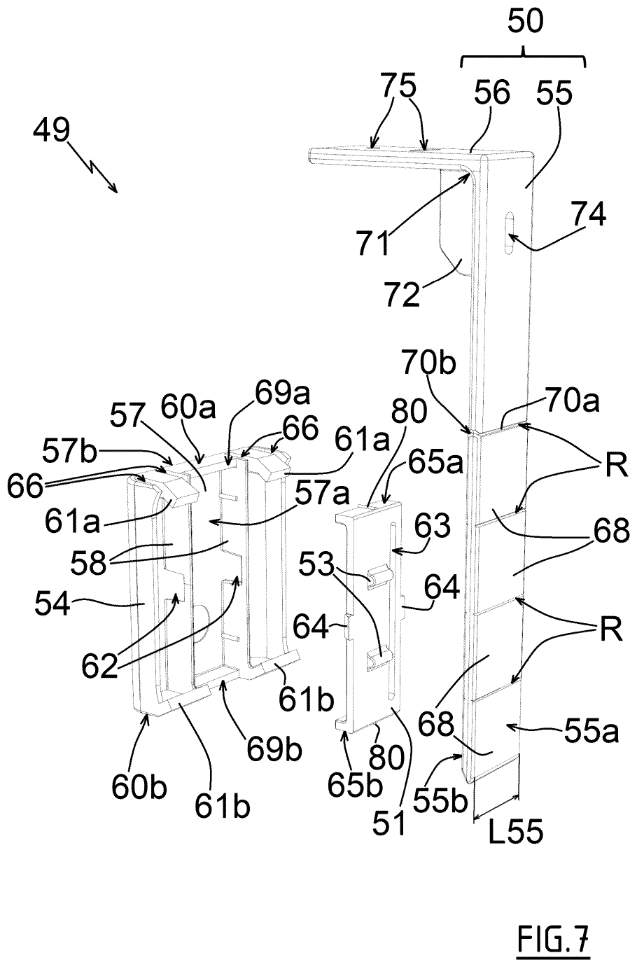

The holding device 51 comprises at least one second locking element 53, as illustrated in FIGS. 7, 9 and 10. The or each second locking element 53 cooperates, in other words is configured to cooperate, with one of the first locking elements 52, in particular in the assembled configuration of the electrical power supply device 31.

Here, the holding device 51 comprises two second locking elements 53.

The number of second locking elements of the holding device is not limiting and can be different. It can be, especially, equal to one or greater than or equal to three.

The fixing device 49 further comprises a cover 54.

The holding device 51 is fixed, in particular in a removable manner, in other words is configured to be fixed or assembled, on the cover 54, in particular in the assembled configuration of the electrical power supply device 31.

The cover 54 is removably fixed, in other words is configured to be removably fixed, on the casing 48, in particular in the assembled configuration of the electrical power supply device 31.

Furthermore, in particular in the assembled configuration of the electrical power supply device 31, the fixing support 50 is arranged, in other words is configured to be arranged, between the casing 48 and the cover 54, so as, on the one hand, to be able to slide the fixing support 50 between the casing 48 and the cover 54 according to a movement in translation T and, on the other hand, to hold the fixing support 50 in position by the holding device 51, during the cooperation of the or each second locking element 53 with one of the first locking elements 52.

Thus, this construction of the electrical power supply device 31 allows to completely dissociate the fixing device 49 relative to the casing 48, on which the photovoltaic panel 25 is fixed.

In this way, this construction of the electrical power supply device 31 allows to adjust the position of the photovoltaic panel 25 relative to the fixing support 50 by means of different adjustment notches obtained by the cooperation of the or each second locking element 53 of the holding device 51 cooperating with one of the first locking elements 52 of the fixing support 50.

The adjustment of the position of the photovoltaic panel 25 relative to the fixing support 50 is therefore implemented without adjustment screws.

Therefore, the adjustment of the position of the photovoltaic panel 25 relative to the fixing support 50 is implemented simply and without using a tool, such as, for example, a screwdriver.

Furthermore, the photovoltaic panel 25 is suspended relative to the fixing support 50 through the casing 48, the holding device 51 and the cover 54.

Moreover, the photovoltaic panel 25 can be mounted on the fixing support 50 or removed from the fixing support 50 by sliding, according to the movement in translation T, a sub-assembly formed by the photovoltaic panel 25, the casing 48, the holding device 51 and the cover 54 relative to the fixing support 50.

Advantageously, the fixing device 49 comprises a single fixing support 50.

Thus, the cost of obtaining the holding device 51 is minimized.

Advantageously, the fixing support 50 is realized in a plastic material.

As a non-limiting example, the plastic material of the fixing support 50 is Poly-Butylene Terephthalate, also called PBT, polyacetal, also called POM, Polyamide 6, also called polycaprolactam or PA 6, Polyamide 6.6, also called polyhexamethylene adipamide or PA 6.6.

Here, the holding device 51 comprises two second locking elements 53. Furthermore, each of the second locking elements 53 cooperates, in other words is configured to cooperate, with one of the first locking elements 52 of the fixing support 50, in particular in the assembled configuration of the electrical power supply device 31.

Thus, the fixing support 50 is held in position relative to the cover 54 and the casing 48 according to the positioning of the two second locking elements 53 of the holding device 51 relative to two first locking elements 52 of the fixing support 50.

In this way, the positioning of the two second locking elements 53 relative to two first locking elements 52 allows to improve the robustness of the holding in position of the fixing support 50 relative to the cover 54 and the casing 48.

Here, the fixing support 50 comprises four first locking elements 52.

Thus, the number of adjustment positions of the fixing support 50 relative to the cover 54 and the casing 48 is equal to three, in the case where the two second locking elements 53 of the holding device 51 are positioned relative to two first locking elements 52 of the fixing support 50.

The number of first locking elements is not limiting and can be different. It can be, for example, equal to two, three or greater than or equal to five.

The number of adjustment positions of the fixing support 50 relative to the cover 54 and the casing 48 depends on the number of first locking elements 52 of the fixing support 50.

Here, the or each first locking element 52 is a recessed element, in other words a cavity. Furthermore, the or each second locking element 53 is a protruding element, in other words a rib.

As a non-limiting example, the section of the recessed element forming the or each first locking element 52 is triangular in shape. Furthermore, the section of the protruding element forming the or each second locking element 53 is semicircular in shape.

In a variant, not represented, the or each first locking element 52 is a protruding element, in other words a rib. In this case, the or each second locking element 53 is a recessed element, in other words a cavity.

Here, the fixing support 50 is a fixing bracket.

Advantageously, the fixing support 50 comprises a first wall 55 and a second wall 56.

Advantageously, the second wall 56 is connected to the first wall 55, so as to form a corner 71 between the second wall 56 and the first wall 55.

Here, the second wall 56 is orthogonal to the first wall 55.

In a variant, not represented, the second wall 56 is inclined relative to the first wall 55 at an angle the value of which is either strictly less than 90°and strictly greater than 0°, preferably strictly greater than 80°, or strictly greater than 90°and strictly less than 180°, preferably strictly less than 100°.

Advantageously, the first wall 55 extends according to a vertical direction, in particular in an assembled configuration of the fixing device 49 relative to the shading installation 6. Furthermore, the second wall 56 extends according to a horizontal direction, in particular in the assembled configuration of the fixing device 49 relative to the shading installation 6.

Advantageously, the fixing support 50 is fixed on a wall, hereafter called a fixed wall, which can be, for example, a wall, not represented, of the box 9, the wall M of the building B, the ceiling P of the building B or the frame 76 of the window 40.

Advantageously, depending on the fixed wall on which the fixing support 50 is fixed, the first wall 55 of the fixing support 50 extends either according to a vertical direction, especially when the fixing support 50 is fixed to the box 9 or the ceiling P of the building B, or according to a horizontal direction, especially when the fixing support 50 is fixed to the wall M of the building B or the frame 76 of the window 40.

Here, the fixing of the fixing support 50 on the fixed wall is implemented by screwing, in this case by means of one or more fixing screws 73.

Advantageously, the first wall 55 of the fixing support 50 comprises at least one first hole 74.

Here and as illustrated in FIGS. 5, 7, 9 and 10, the first wall 55 comprises a single first hole 74. The first hole 74 is oblong in section, in particular with its greatest dimension parallel to a length of the first wall 55.

Here, the fixing of the fixing support 50 on the fixed wall, in this case in the box 9, as illustrated in FIG. 10, is implemented by a fixing screw 73 passing through the first hole 74 and screwing into a fixing hole of the fixed wall.

Advantageously, the second wall 56 of the fixing support 50 comprises at least one second hole 75.

Here and as illustrated in FIGS. 5 to 8, the second wall 56 comprises two second holes 75. One of the second holes 75 is circular in section and the other of the second holes 75 is oblong in section, in particular with its greatest dimension perpendicular to a length of the second wall 56.

Here, the fixing of the fixing support 50 on the fixed wall, in this case the ceiling P of the building B, as illustrated in FIG. 9, is implemented by two fixing screws 73 passing respectively through one of the second holes 75 and screwing into the fixed wall or, in a variant, not represented, into a dowel, which is fixed in the fixed wall.

Advantageously, the first locking elements 52 are provided in the first wall 55 of the fixing support 50.

Advantageously, the fixing of the cover 54 on the casing 48 is implemented by elastic snap-fit.

Advantageously, the casing 48 comprises at least a first groove 59a and a second groove 59b.

Here, the first and second grooves 59a, 59b extend according to a width L of the casing 48 between the first and second ends 48a, 48b of the casing 48 and, advantageously, over the entire width L of the casing 48.

Advantageously, the casing 48 comprises a first edge 48c, which can also be called “upper edge”, and a second edge 48d, which can also be called “lower edge”. The second edge 48d is opposite the first edge 48c. Furthermore, the first groove 59a is arranged near the first edge 48c and the second groove 59b is arranged near the second edge 48d.

Here and as illustrated in FIGS. 5 and 6, the fixing support 50 is arranged centrally relative to the casing 48, according to the width L of the casing 48 between the first and second ends 48a, 48b of the casing 48.

Advantageously, the cover 54 comprises at least a first edge 60a and a second edge 60b. The second edge 60b is opposite the first edge 60a.

Advantageously, the cover 54 further comprises at least one notch 69a, 69b. Furthermore, the fixing support 50, in particular the first wall 55 of the fixing support 50, is configured to slide, in other words slides, between the casing 48 and the cover 54 according to the movement in translation T through the or each notch 69a, 69b.

Here, the cover 54 comprises a first notch 69a provided at the first edge 60a of the cover 54 and a second notch 69b provided at the second edge 60b of the cover 54.

Thus, during the sliding of the fixing support 50 relative to the cover 54 and the casing 48 according to the movement in translation T or during the holding in position of the fixing support 50 relative to the cover 54 and the casing 48, the fixing support 50, in particular the first wall 55 of the fixing support 50, extends through the first notch 69a of the cover 54 and, eventually, through the second notch 69b of the cover 54.

In a variant, not represented, the cover 54 comprises a single notch 69a, 69b, which is provided either at the first edge 60a of the cover 54 or at the second edge 60b of the cover 54. Thus, during the sliding of the fixing support 50 relative to the cover 54 and the casing 48 according to the movement in translation T or during the holding in position of the fixing support 50 relative to the cover 54 and the casing 48, the fixing support 50, in particular the first wall 55 of the fixing support 50, extends through the single notch 69a, 69b of the cover 54.

Advantageously, the cover 54 further comprises at least one first lug 61a and at least one second lug 61b. The or each first lug 61a is arranged along the first edge 60a of the cover 54. The or each second lug 61b is arranged along the second edge 60b of the cover 54. Furthermore, the or each first lug 61a is elastically deformable.

Advantageously, the fixing of the cover 54 on the casing 48 is implemented by inserting the or each first lug 61a into the first groove 59a and by inserting the or each second lug 61b into the second groove 59b.

Here, the cover 54 comprises two first lugs 61a, which are arranged respectively along the first edge 60a, and two second lugs 61b, which are arranged respectively along the second edge 60b.

Advantageously, the two first lugs 61a are arranged on either side of the first notch 69a. Furthermore, the two second lugs 61b are arranged on either side of the second notch 69b.

The number of first lugs and the number of second lugs of the cover are not limiting and can be different. They can, for example, be equal to one or greater than or equal to three.

Advantageously, the cover 54 further comprises a slit 66 on each side of each first lug 61a.

Thus, the slit 66 on each side of the or each first lug 61a allows the elastic deformation of the or each first lug 61a to be guaranteed, so as to fix the cover 54 on the casing 48 by elastic snap-fit.

In a variant, not represented, the or each second lug 61b is elastically deformable. In this case, the cover 54 further comprises, in addition to or instead of the slit 66 on each side of the or each first lug 61a, a slit 66 on each side of the or each second lug 61b.

The deformable nature of the first and/or second lugs 61a, 61b facilitates the assembly of the cover 54 on the casing 48, in particular by elastic snap-fit, as well as its dismantling.

Advantageously, the cover 54 further comprises two cutouts 62.

Advantageously, the holding device 51 further comprises two protruding elements 64 and at least one slot 63. Each protruding element 64 is housed, in other words is configured to be housed, inside one of the cutouts 62 of the cover 54, in particular in the mounted configuration of the holding device 51 in the cover 54, therefore in the assembled configuration of the fixing device 49.

Advantageously, the cover 54 further comprises a wall 57 and two ribs 58. Furthermore, each rib 58 comprises at least one of the cutouts 62.

Advantageously, the wall 57 of the cover 54 comprises an outer face 57a and an inner face 57b. The inner face 57b is opposite the outer face 57a.

Advantageously, each cutout 62 extends from one of the ribs 58 to the inner face 57b of the wall 57 of the cover 54.

Advantageously, a part of the holding device 51 is elastically deformed by means of the slot 63, during the insertion of each protruding element 64 inside one of the cutouts 62 of the cover 54.

Thus, the assembly of the holding device 51 relative to the cover 54 is implemented by an elastic deformation of a part of it, by means of the slot 63, so as to insert each protruding element 64 of the holding device 51 inside one of the cutouts 62 of the cover 54.

Advantageously, the insertion of each protruding element 64 of the holding device 51 inside one of the cutouts 62 of the cover 54 is implemented by the elastic deformation of the holding device 51, by means of the slot 63.

Thus, when an elastic deformation force exerted on the holding device 51, in particular by pinching at the slot 63, is released, in other words when the holding device 51 is no longer subjected to elastic deformation force, each protruding element 64 inserted inside one of the cutouts 62 allows the holding in position of the holding device 51 relative to the cover 54 to be guaranteed.

In a variant or in addition, the insertion of each protruding element 64 of the holding device 51 inside one of the cutouts 62 of the cover 54 is implemented by an elastic deformation by spreading the two ribs 58 respectively comprising the cutouts 62.

Thus, when an elastic deformation force exerted on the ribs 58 of the cover 54 is released, in other words when the ribs 58 of the cover 54 are no longer subjected to elastic deformation coming from the protruding elements 64 of the holding device 51, each protruding element 64 inserted inside one of the cutouts 62 allows the holding in position of the holding device 51 relative to the cover 54 to be guaranteed.

Advantageously, the holding device 51 is arranged, in other words is configured to be arranged, between the first and second edges 60a, 60b of the cover 54, in particular in the assembled configuration of the fixing device 49.

Advantageously, the holding device 51 further comprises a first border 65a and a second border 65b. The second border 65b is opposite the first border 65a. Furthermore, in particular in the assembled configuration of the fixing device 49, the first border 65a of the holding device 51 is arranged, in other words is configured to be arranged, in front of the first edge 60a of the cover 54 and the second border 65b of the holding device 51 is arranged, in other words is configured to be arranged, in front of the second edge 60b of the cover 54.

Advantageously, each of the first and second borders 65a, 65b of the holding device 51 is in abutment, in other words is configured to abut, against one of the first and second edges 60a, 60b of the cover 54, in particular in the assembled configuration of the fixing device 49.

Advantageously, the bearing of each of the first and second borders 65a, 65b of the holding device 51 against one of the first and second edges 60a, 60b of the cover 54 is implemented by means of at least one rib 80 provided on each of the first and second borders 65a, 65b.

Here, each of the first and second borders 65a, 65b of the holding device 51 comprises a single rib 80.

The number of ribs on each of the first and second borders of the holding device is not limiting and can be different. It can be, for example, greater than or equal to two.

Advantageously, each of the first and second borders 65a, 65b of the holding device 51 is, in addition, in abutment, in other words is configured to be, in addition, in abutment, against the inner face 57b of the wall 57 of the cover 54, in particular in the assembled configuration of the fixing device 49.

Advantageously, the fixing support 50 is breakable by means of break lines R.

Advantageously, each of the break lines R extends through one of the first locking elements 52 of the fixing support 50.

Thus, the fixing support 50 presents breakable parts 68 allowing one or more of them to be removed, by means of the break lines R. The breakable part(s) 68 to be removed are delimited by one of the first locking elements 52 that is unused to guarantee the holding in position of the fixing support 50 relative to the holding device 51.

In this way, the aesthetic aspect of the fixing device 49 is improved by removing one or more breakable parts 68, so as to avoid an overhang of the fixing support 50, in particular of the first wall 55 of the first fixing support 50, relative to the cover 54, in particular through the second notch 69b.

Advantageously, the break lines R are provided in the first wall 55 of the fixing support 50.

Advantageously, each of the break lines R extends according to a width L55 of the first wall 55 of the fixing support 50 and, preferably, over the entire width L55 of the first wall 55.

Here, each of the break lines R is realized by at least one groove 70a, 70b.

Advantageously, the first wall 55 of the fixing support 50 comprises a first face 55a and a second face 55b. The second face 55b is opposite the first face 55a.

Advantageously, each of the break lines R comprises a first groove 70a provided on the first face 55a of the first wall 55 and a second groove 70b provided on the second face 55b of the first wall 55. The second groove 70b is arranged vis-a-vis the first groove 70a, in particular according to the length of the first wall 55.

Advantageously, the fixing support 50 further comprises at least one stop 72. The or each stop 72 is provided in the corner 71 of the fixing support 50.

Thus, the or each stop 72 allows to reinforce the fixing support 50 at the junction between the first and second walls 55, 56.

Here, the fixing support 50 comprises two stops 72, only one of which is represented in FIGS. 5, 7, 9 and 10. Furthermore, each of the stops 72 is provided in the corner 71 of the fixing support 50.

The number of stops is not limiting and can be different. It can be, for example, be equal to one or greater than or equal to three.

In the embodiment illustrated in FIG. 10, the box 9 is in abutment, in other words is configured to be in abutment, against the or each stop 72, in particular in the assembled configuration of the shading device 3.

Thus, the or each stop 72 allows to guarantee a space between the box 9 and the fixing support 50, in particular between the box 9 and the first wall 55 of the fixing support 50.

In this way, the spacing between the box 9 and the fixing support 50 guaranteed by the or each stop 72 allows to prevent the fixing screw(s) 73 from coming into contact with the screen 2, even though they can protrude inside the box 9.

Furthermore, the positioning of the box 9 against the two stops 72 of the fixing support 50 allows to guarantee the parallelism between the box 9 and the first wall 55 of the fixing support 50.

Thanks to the invention, the construction of the electrical power supply device allows the complete dissociation of the fixing device relative to the casing, on which the photovoltaic panel is fixed.

Many modifications can be made to the embodiments described above, without departing from the scope of the invention defined by the claims.

In a variant, not represented, in the case where the photovoltaic panel 25 is fixed on the casing 48, the electrical connection between the electrical power cable 18 and the photovoltaic panel 25 is implemented by assembling an electrical connector of the electrical power cable 18 on another electrical connector of the photovoltaic panel 25.

In a variant, not represented, the electronic control unit 15 further comprises a housing. Furthermore, the first electronic board 15a is arranged inside the housing, in particular in an assembled configuration of the electronic control unit 15. Thus, the housing of the electronic control unit 15 allows to protect the first electronic board 15a, during the assembly of the electromechanical actuator 11 and after its assembly. In this way, the housing of the electronic control unit 15 allows to isolate electrically the first electronic board 15a relative to the casing 17. Advantageously, the outer diameter of the housing of the electronic control unit 15 is smaller than the inner diameter of the casing 17, so that the housing can be inserted into the casing 17, during the assembly of the electromechanical actuator 11. In a first case, the housing of the electronic control unit 15 can comprise two half-shells configured to cooperate together, in particular in the assembled configuration of the electronic control unit 15. In the assembled configuration of the electromechanical actuator 11, the two half-shells are assembled together, so as to define a junction plane extending according to a direction parallel to the rotation axis X. Advantageously, at least one of the two half-shells forming the housing comprises positioning and fixing elements for the first electronic board 15a, in particular in the assembled configuration of the electronic control unit 15. In a second case, the housing of the electronic control unit 15 can comprise one or more sections, the or each section being realized in the form of a hollow tube. The or each section is configured to house or receive, in other words houses or receives, the first electronic board 15a, in particular in the assembled configuration of the electronic control unit 15. In such a case, the or each section of the housing comprises a first groove and a second groove. Furthermore, the first and second grooves are configured to hold in position, in other words hold in position, the first electronic board 15a inside the housing, in particular in the assembled configuration of the electronic control unit 15.

In a variant, not represented, the electrical power supply device 31 further comprises a charger. The charger is configured to be electrically connected, in other words is electrically connected, to the battery 46, either directly, or through the electromechanical actuator 11 and/or the electronic control unit 15. The charger is configured to be plugged, in other words is plugged, into a wall electrical outlet, so as to recharge the battery 46 from a mains power supply network. This charger forms an external electrical power supply source.

In a variant, not represented, the electrical power supply device 31 further comprises an auxiliary battery, the auxiliary battery being configured to recharge the battery 46. The auxiliary battery is configured to be electrically connected, in other words is electrically connected, to the battery 46, either directly, or through the electromechanical actuator 11 and/or the electronic control unit 15. Thus, the battery 46 can be recharged by means of the auxiliary battery forming an external electrical power supply source, in particular in the case where the shading device 3 is far from a wall electrical outlet. Furthermore, the auxiliary battery can allow the recharging of a battery of other electrical equipment, especially mobiles ones, such as, for example, a mobile phone or a laptop.

In a variant, not represented, the electromechanical actuator 11 is inserted into a rail, in particular of square or rectangular section, which can be open at one or both ends, in particular in the assembled configuration of the shading device 3. Furthermore, the electromechanical actuator 11 can be configured to drive at least one drive shaft on which displacement and/or orientation cords of the screen 2 are wound, which can, advantageously, be a blind with slats in this case. In this case, the shading device 3 comprises a movable bar or a plurality of movable bars, which can all be displaced by means of the electromechanical actuator 11.

Furthermore, the contemplated embodiments and variants can be combined to generate new embodiments of the invention, without departing from the scope of the invention defined by the claims.

1. An electrical power supply device,
the electrical power supply device comprising at least
a casing,
a photovoltaic panel, the photovoltaic panel being fixed on the casing, and
a fixing device,
the fixing device comprising at least
a fixing support, the fixing support comprising at least a plurality of first locking elements, and
a holding device, the holding device comprising at least one second locking element, said at least one second locking element cooperating with one of the first locking elements,
wherein
the fixing device further comprises a cover,
the holding device is fixed on the cover,
the cover is removably fixed on the casing,
and the fixing support is arranged between the casing and the cover, so as, on the one hand, to be able to slide the fixing support between the casing and the cover according to a movement in translation and, on the other hand, to hold the fixing support in position by the holding device, during the cooperation of said at least one second locking element with one of the first locking elements.

2. The electrical power supply device according to claim 1, wherein the fixation of the cover on the casing is implemented by elastic snap-fit.

3. The electrical power supply device according to claim 2, wherein
the casing comprises at least
a first groove, and
a second groove,
the cover comprises at least:
a first edge,
a second edge, the second edge being opposite the first edge,
a first lug, the or each first lug being arranged along the first edge, the or each first lug being elastically deformable, and
a second lug, the or each second lug being arranged along the second edge, and the fixing of the cover on the casing is implemented by inserting the or each first lug into the first groove and by inserting the or each second lug into the second groove.

4. The electrical power supply device according to claim 1, wherein
the cover further comprises two cutouts,
the holding device further comprises two protruding elements and at least one slot, each protruding element being housed inside one of the cutouts,
and a part of the holding device is elastically deformed by means of the slot, during the insertion of each protruding element inside one of the cutouts of the cover.

5. The electrical power supply device according to claim 1, wherein the fixing support is breakable by means of break lines.

6. The electrical power supply device according to claim 5, wherein each of the break lines extends through one of the first locking elements.

7. A motorized driving device,
the motorized driving device comprising at least
an electromechanical actuator,
an electronic control unit, and
an electrical power supply device,
the electromechanical actuator comprising at least one electric motor,
wherein
the electrical power supply device is according claim 1,
the electrical power supply device further comprises a battery,
and the electronic control unit and the electric motor are supplied in electrical energy from the battery.

8. The motorized driving device according to claim 7, wherein the battery is supplied in electrical energy by means of the photovoltaic panel.

9. A shading device,
the shading device comprising at least
a screen, and
a motorized driving device,
wherein the motorized driving device is according to claim 7, the screen being configured to be driven in displacement by the electromechanical actuator of the motorized driving device.

10. The shading device according to claim 9, wherein
the shading device further comprises at least one box, the electromechanical actuator being housed inside the box,
the fixing support comprises at least
a first wall,
a second wall, the second wall being connected to the first wall, so as to form a corner between the second wall and the first wall, and
a stop, the or each stop being provided in the corner,
and the box is in abutment against the or each stop.

11. The electrical power supply device according to claim 2, wherein
the cover further comprises two cutouts,
the holding device further comprises two protruding elements and at least one slot, each protruding element being housed inside one of the cutouts,
and a part of the holding device is elastically deformed by means of the slot, during the insertion of each protruding element inside one of the cutouts of the cover.

12. The electrical power supply device according to claim 3, wherein
the cover further comprises two cutouts,
the holding device further comprises two protruding elements and at least one slot, each protruding element being housed inside one of the cutouts,
and a part of the holding device is elastically deformed by means of the slot, during the insertion of each protruding element inside one of the cutouts of the cover.

13. The electrical power supply device according to claim 2, wherein the fixing support is breakable by means of break lines.

14. The electrical power supply device according to claim 3, wherein the fixing support is breakable by means of break lines.

15. The electrical power supply device according to claim 4, wherein the fixing support is breakable by means of break lines.

16. A motorized driving device,
the motorized driving device comprising at least
an electromechanical actuator,
an electronic control unit, and
an electrical power supply device,
the electromechanical actuator comprising at least one electric motor,
wherein
the electrical power supply device is according claim 2,
the electrical power supply device further comprises a battery,
and the electronic control unit and the electric motor are supplied in electrical energy from the battery.

17. A motorized driving device,
the motorized driving device comprising at least
an electromechanical actuator,
an electronic control unit, and
an electrical power supply device,
the electromechanical actuator comprising at least one electric motor,
wherein
the electrical power supply device is according claim 3,
the electrical power supply device further comprises a battery,
and the electronic control unit and the electric motor are supplied in electrical energy from the battery.

18. A motorized driving device,
the motorized driving device comprising at least
an electromechanical actuator,
an electronic control unit, and
an electrical power supply device,
the electromechanical actuator comprising at least one electric motor,
wherein
the electrical power supply device is according claim 4,
the electrical power supply device further comprises a battery,
and the electronic control unit and the electric motor are supplied in electrical energy from the battery.

19. A motorized driving device,
the motorized driving device comprising at least
an electromechanical actuator,
an electronic control unit, and
an electrical power supply device,
the electromechanical actuator comprising at least one electric motor,
wherein
the electrical power supply device is according claim 5,
the electrical power supply device further comprises a battery,
and the electronic control unit and the electric motor are supplied in electrical energy from the battery.

20. A motorized driving device,
the motorized driving device comprising at least
an electromechanical actuator,
an electronic control unit, and
an electrical power supply device,
the electromechanical actuator comprising at least one electric motor,
wherein
the electrical power supply device is according claim 6,
the electrical power supply device further comprises a battery,
and the electronic control unit and the electric motor are supplied in electrical energy from the battery.
